(19) United States
(12) Patent Application Publication
(10) Pub. No.: US 2007/0120173 A1
(43) Pub. Date: May 31, 2007

(54) Non-volatile memory cell with high current output line

(76) Inventor: Bohumil Lojek, Colorado Springs, CO (US)

Correspondence Address: SCHNECK & SCHNECK, P.O. BOX 2-E, SAN JOSE, CA, 95109-0005, US

(21) Appl. No.: 11/288,660

(22) Filed: Nov. 28, 2005

(51) Int. Cl. H01L 29/788

(52) U.S. Cl. 257/315

(57) ABSTRACT

A memory cell having a low current memory device and a relatively high current output amplifier device, all built in the areawise footprint occupied by the memory device only. The low current memory device is a layered n-MOS or p-MOS lateral device having laterally spaced source and drain electrodes in a substrate and floating and control gates above the source and drain. The relatively high current output amplifier device is formed by contacts with layers or regions within layers having opposite conductivity types such that p-n junctions are arranged in forward and reverse bias configurations. These configurations form a vertical bipolar transistor that is beneath at least a portion of the lateral memory device and within the same footprint. The vertical bipolar transistor is connected as an output driver or amplifier for the memory device. An array of similar devices forms a memory array. The memory device can be a single transistor flash device or a single transistor EEPROM with a select transistor or other MOS memory device configuration.

### TECHNICAL FIELD

The invention relates to non-volatile memory cells and, in particular, to a new memory cell optimized for driving an output line.

### BACKGROUND ART

Non-volatile memory cells are arranged in rows and columns to form memory arrays. In a NOR EEPROM memory array, each memory cell may be accessed individually with specific word lines and bit lines. Any memory cell that is ON, i.e. a selected erased cell, results in current on a source line that can be read or sensed by a sense amplifier. In recent years, the reduction in memory cell size to achieve higher memory array sizes has resulted in a reduction of the cell current during the read operation. Cell currents on the order of 20-30 microamps are typical. However, smaller non-volatile memory devices now being offered will result in cell output current that will also become smaller due to lower voltages and higher resistivity of connective lines. Cell currents on the order of one microamp are foreseeable. Such low currents will be difficult to reliably distinguish from noise.

A NAND flash memory array also has rows and columns of memory cells in an array but the logical organization of the array is in chains of memory cells where data is sensed serially through the chain, allowing NAND memory arrays to emulate disk drives and the like. The output of one memory cell becomes the input for an adjacent cell. But small output currents from one cell, arising from the reasons mentioned above, may be insufficient to drive the adjacent cell.

The problem of low output current could be addressed by line drivers. For example, line drivers could be current amplifiers placed at locations to boost weak currents to sufficient levels for reading. However, such line drivers could significantly add to overhead circuitry of a memory array.

Both NOR and NAND memory arrays employ floating gate transistors in the memory cell. There are at least two basic types of cells: a one transistor cell usually associated with “flash” memory arrays, and a two transistor cell usually associated with “EEPROM” memory arrays. There are cells with greater numbers of transistors but most can be classified as either of the two basic types. In flash memory arrays, i.e. block erase types, a single floating gate memory cell is used, with charge stored on the floating gate, or lack of charge, determining the conduction state of the transistor. For example, an erased floating gate leads to an ON transistor, i.e. conduction between source and drain, representing one memory state. A programmed floating gate leads to an OFF transistor, i.e. no conduction between source and drain. The conduction state of the transistor is sensed by a sense amplifier associated with the source or drain of the transistor. With microamp currents, sensing becomes difficult and subject to error.

In non-flash memories, i.e. random access EEPROM arrays where two transistor memory cells are used, one transistor is a floating gate memory transistor, as above, and a second transistor, in series with the first, is known as a select transistor. The problem of low current for read sensing arises for the same reasons as in the single transistor cell.

One of the well known problems in semiconductor CMOS memory devices of reduced size is that of errors arising from parasitic subsurface p-n junctions in a phenomenon known as latch-up. Strong efforts are made to prevent latch-up where parasitic p-n junctions arrange themselves as pnp and npn bipolar transistors that can dominate circuit behavior. Sometimes parasitic transistors of one conductivity type cooperate with parasitic transistors of the other conductivity type. The strategies for avoiding latch-up usually involve spoiling the formation of bipolar transistors or decoupling one parasitic transistor from communicating with another parasitic transistor.

An object of the invention is to devise a p-MOS or n-MOS memory cell that operates at low current yet has significant drive current for memory state output to a sense amplifier and not subject to latch-up.

### SUMMARY OF THE INVENTION

The above object has been achieved with a p-MOS or n-MOS memory cell that employs parasitic subsurface bipolar transistors in a positive manner. Instead of treating parasitic bipolar transistors as a problem, the present invention establishes subsurface bipolar transistors that might appear to be unwanted parasitic transistors but are actually useful current amplifiers with substantial gain. In particular, a subsurface vertical bipolar transistor is combined with a lateral MOS non-volatile memory device of the type having a floating gate to amplify the current output of the memory device, with both devices in the same areawise device footprint. In this manner, a memory device of the present invention carries its own output driver, reducing any need for external output drivers for sense amplifiers or the like. For example, a vertical pnp transistor is built beneath the lateral MOS memory transistor. There is no restriction on the type of floating gate memory device, whether single transistor or two transistor, the two transistor type including a select transistor and possibly other auxiliary transistors. Also, there is no restriction on the type of memory array in which memory devices of the present invention may be used. They may be used in NOR and NAND arrays.

Although there is no restriction on the type of non-volatile memory device used in the present invention, it is preferred that a lateral or layered construction method be employed which is typical for such devices. The use of lateral or layered construction, including ion implantation, allows for simultaneous formation of subsurface vertical bipolar structures in the same areawise footprint. Although the combination of a lateral structure and a vertical structure is known in the prior art, such structures are not part of memory arrays. Specifically, a non-volatile memory device is built in a layered construction with a floating gate electrically insulated from source and drain but with the floating gate in electrical charge carrier communication with at least one of the source, drain and substrate.

Among the layers within the substrate is a plurality of p-n junctions some of which are biased to form a bipolar transistor with at least one electrode communicating with one of the source and drain of the non-volatile memory device so that the bipolar transistor can be an output driver for the memory device.

### BRIEF DESCRIPTION OF THE DRAWINGS

FIG. 1 is a plan view of a non-volatile flash memory cell with a high current provided for an output line in accordance with the present invention.

FIG. 2 is a plan view of an alternate embodiment of the device of FIG. 1, namely an EEPROM memory cell with high current for an output line.

FIG. 3 is a plan view of a NOR memory array employing memory cells shown in FIG. 2.

FIG. 4 is a plan view of a NAND memory array employing memory cells shown in FIG. 2.

### BEST MODE FOR CARRYING OUT THE INVENTION

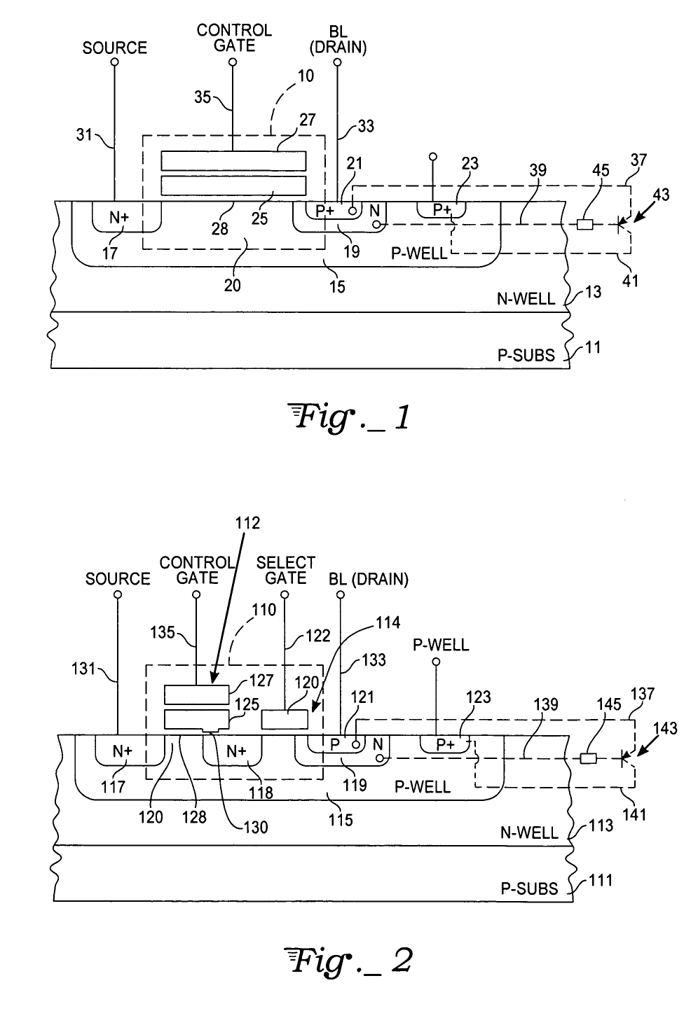

With reference to FIG. 1, a non-volatile flash memory transistor shown within dashed line block 10 is formed on and in a p-type semiconductor substrate 11, typically a silicon wafer. The overall drawing depicts structures in the active area of a memory cell on the wafer, usually defined by isolation regions, not shown. The active area defines the areawise footprint of the cell.

The substrate 11 has an n-type epitaxial layer grown thereon such that the layer appears as a deep n-well 13. A shallow p-well 15 is established in the epi n-well layer 13 by diffusion or implantation. Within the p-well 15 a shallow source region 17 is established by ion implantation as an n+ region. A similar n-type drain region 19, less negative than the n+ source region, is similarly established in a spaced-apart relation so that a channel region 20 can exist between source and drain. The reduced conductivity of drain region 19 simulates an impedance 45. A shallow p+ region 21 is implanted in the n-type drain 19, giving rise to a p-n junction at the boundary of regions 19 and 21. Similarly, the n-type drain 19 forms an n-p junction relative to the p-well 15 at the boundary of p-well 15 and n-type drain 19. A p+ implant region 23 in p-well 15 allows external connection to the p-well.

A polysilicon floating gate 25 is located above the surface 28 of the substrate and associated layers, near spaced apart mutually facing edges of source 17 and drain 19, being separated from the substrate by a thin layer of tunnel oxide. A control gate 27, insulatively spaced over the floating gate 25, influences charge carrier transfer onto the floating gate 25 or out of the floating gate in relation to one of the source 17 or drain 19. Charge on the floating gate signifies a digital logic state, one or zero, with the erased floating gate signifying the opposite state. The state of the floating gate regulates conduction of the memory transistor 10. For example, charge on the floating gate could pinch off the channel 20 and stop source to drain conduction, meaning that the transistor is OFF. Lack of charge on the floating gate allows conduction through the channel from source to drain and the transistor 10 is ON. A sense amplifier connected to source line 31 could detect the conductivity state of the transistor 10. The strength of current conduction, i.e. the current amount through the channel, is enhanced in accordance with the present invention.

If the p-n junction is reverse biased and the n-p junction is forward biased a virtual or parasitic pnp transistor 43 is formed using imaginary emitter line 37, imaginary base line 39 and imaginary collector line 41, the imaginary lines indicated by dashed lines. Collector line 41 is associated with the p-well 15 and the p-well contact 23. An imaginary base impedance 45, associated with reduced conductivity of the n-type drain 19, develops the transistor bias. The imaginary lines and the depiction of the parasitic transistor 43 are for purposes of explanation and illustration of the action of the p-n and n-p junctions. The p+ region 21 is connected to bit line 33 as well as to emitter line 37. The source region 17 is connected to source line 31.

Base current to pnp transistor 43 is supplied from the n+ source region 17 flowing through the channel of the floating gate device 10, i.e. when the device is erased. Positive bias on bit line 33, hence on emitter line 37 will forward bias the emitter-base junction associated with lines 37 and 39 while the voltage developed on impedance 45 will help reverse bias the n-p base-collector junction associated with lines 39 and 41, thereby causing the bipolar pnp transistor 43 to conduct.

The bipolar transistor 43 is a vertical structure formed by base-emitter and base-collector junctions that are an integral part of flash memory transistor 10. The base-emitter p-n junction arises from the adjacent contact of emitter implant 21 with drain region 19. The base collector n-p junction arises from the adjacent contact of drain region 19 with p-well 15. If charge stored on floating gate 25 causes memory transistor 10 to be in the OFF state then there is no base current to the bipolar transistor 43 and no current flow through bit line 33. On the other hand, if lack of charge stored on floating gate 25 causes memory transistor 10 to be in the ON state, then there is base current to the bipolar transistor 43 and current amplified by the bipolar transistor 43 will flow through bit line 33. In this manner, the bipolar transistor 43 is a driver device for bit line 33, amplifying the output read current signal of the memory device 10. The gain of the bipolar transistor 43 could typically be less than 50 microamps. This means that a normal one microamp output current supplied by the memory transistor 10 without assistance of bipolar transistor 43 becomes a cell current of up to 50 microamps assisted by the bipolar transistor 43. The memory device 10 is not restricted to any particular kind of flash memory device but may be any known flash cell.

With reference to FIG. 2, an EEPROM memory transistor cell 110 is shown within dashed line block and formed on and in a p-type semiconductor substrate 111. Within the dashed line block containing memory transistor cell 110 are two transistors including a non-volatile EEPROM memory transistor 112 to the left and a select transistor 114 to the right. The memory transistor 112 and select transistor 114 work together as an EEPROM memory cell in a memory array.

The substrate 111 has an epitaxial n-type layer 113 grown thereon such that the layer appears as a deep n well. A p well 115 is established in the n well layer 113 by diffusion or implantation, as in FIG. 1. Within the p well 115 two lesser regions are formed, namely a shallow source region 117 and a shallow drain region 118 are established as n+ regions, typically by ion implantation. The drain region 118 acts as a source region for the select transistor 114 and a shallow n type implantation region 119 within p well 115 is the drain for the select transistor of the memory cell 110. An even more shallow p region 121 is implanted in the n-type drain implant region 119 to form a p-n junction for bit line 133. In this manner, subsurface implantation regions are available to serve as source and drain for the memory transistor 112 as well as for the select transistor 114. An additional implantation region 123 in p well 115, slightly spaced from the n drain implant region 119 serves as a p well contact. The floating gate 125 is spaced above surface 128 by a thin layer of tunnel oxide at the tunnel window region 130. Thicker oxide surrounds the tunnel oxide and separates both the floating gate 125 and the select gate 120 from the surface 128. Another oxide layer insulates control gate 127 from floating gate 125. Electrical charge is communicated from drain region 118 to and from floating gate 125 by Fowler-Norheim tunneling.

In FIG. 2, a p-n junction is formed between the implant regions 121 and 119. An n-p junction is formed between n-type implant region 119 and the p well 115. If the p-n junction is reverse biased and the n-p junction is forward biased, a pnp transistor 143 is formed using imaginary emitter line 137, imaginary base line 139, and imaginary collector line 141, associated with the p-well 115 and the p-well contact 123. Imaginary impedance 145 develops the transistor bias in a manner similar to impedance 45 in FIG. 1. The imaginary lines and the parasitic transistor 143 are for purposes of explanation of the action of the p-n and n-p junctions. Base current to the pnp transistor 143 is supplied from the n+ source region 117 flowing through the channel of floating gate device 112 when electric charge does not prevent operation of the channel. Positive bias on bit line 133, transferring bias to the emitter line 137 will forward bias the emitter-base junction associated with lines 137 and 139 while voltage developed on impedance 145 will reverse bias the n-p base-collector junction associated with lines 139 and 141 thereby causing the bipolar transistor 143 to conduct. As with FIG. 1, the pnp transistor 143 is a vertical structure built below a memory cell.

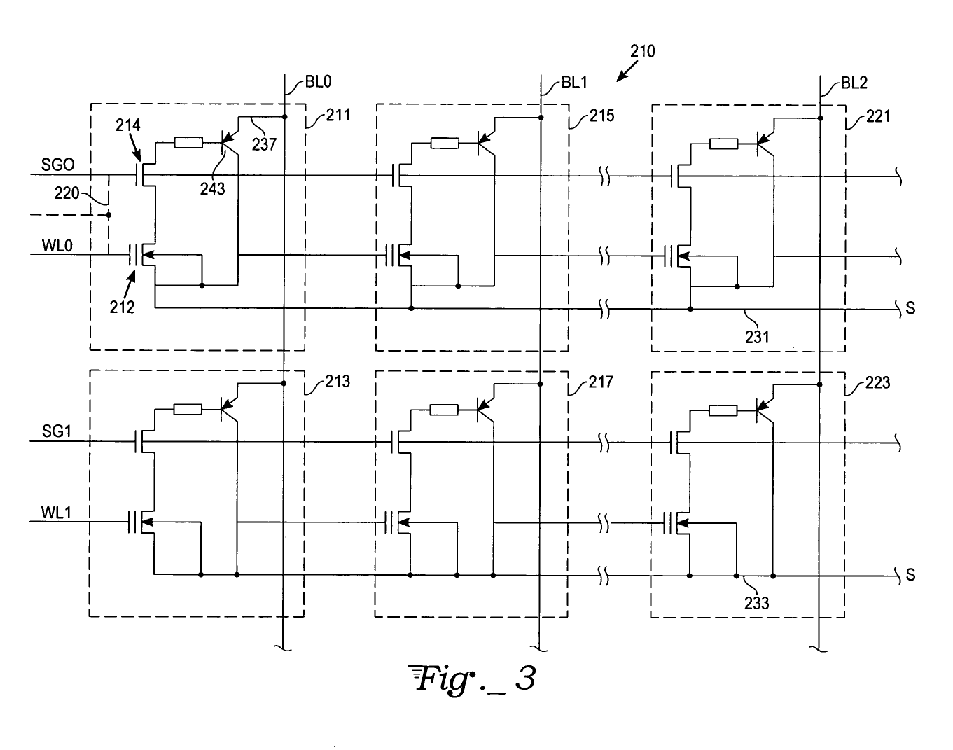

With reference to FIG. 3, a NOR EEPROM array 210 is shown having representative cells 211 and 213 in a first column and representative cells 215 and 217 in a second column and so on to cells 221 and 223 in a last column. Each cell is of the type shown in FIG. 2.

The first column of cells with cells 211 and 213 has vertical bit line zero, BL0, while the second column of cells with cells 215 and 217 has vertical bit line one, BL1, and the last column of cells with cells 221 and 223 has vertical bit line two, BL2. Each bit line is connected to the emitter of the pnp transistor associated with each cell, such as emitter line 237 of pnp transistor 243 connected to BL0. The cell 211 has a select transistor 214 and a floating gate memory transistor 212. A zero order select gate line, SG0, is connected to the select gate of select transistor 214 and to each select gate in the top row of cells. Similarly the next row of cells has a first order select gate line, SG1, connected to the select gate of the select transistor in that row.

Returning to the top row of cells, the zero order word line, WL0, is connected to the control gate of memory transistor 212 and to a corresponding gate of each memory transistor in the top row of cells. An alternative connection of word line WL0 to select gate SG0 is indicated by dashed line 220. In the top row, a common source line 231 connects sources of all memory devices in a row starting with the source line of memory device 212. In the next row, common source line 233 connects sources of all memory devices in the next row. Typical voltages are as follows:

Program

| | |
|---|---|
| Row (Selected) | All other rows (Unselected) |

| | | | |
|---|---|---|---|
| SGO | +8V | SG1 | GND |
| WLO | +8V | WL1 | GND ÷ −4V |
| BL_{SEL} | −8V | BL_{UNSEL} | −8V |
| S | −8V | S | +2V |

Erase

| | |
|---|---|
| Row (Selected) | All other rows (Unselected) |

| | | | |
|---|---|---|---|
| SGO | +8V | SG1 | GND |
| WLO | −8V | WL1 | GND ÷ +4V |
| BL_{SEL} | +8V | BL_{UNSEL} | GND |
| S | +8V | S | +4V |

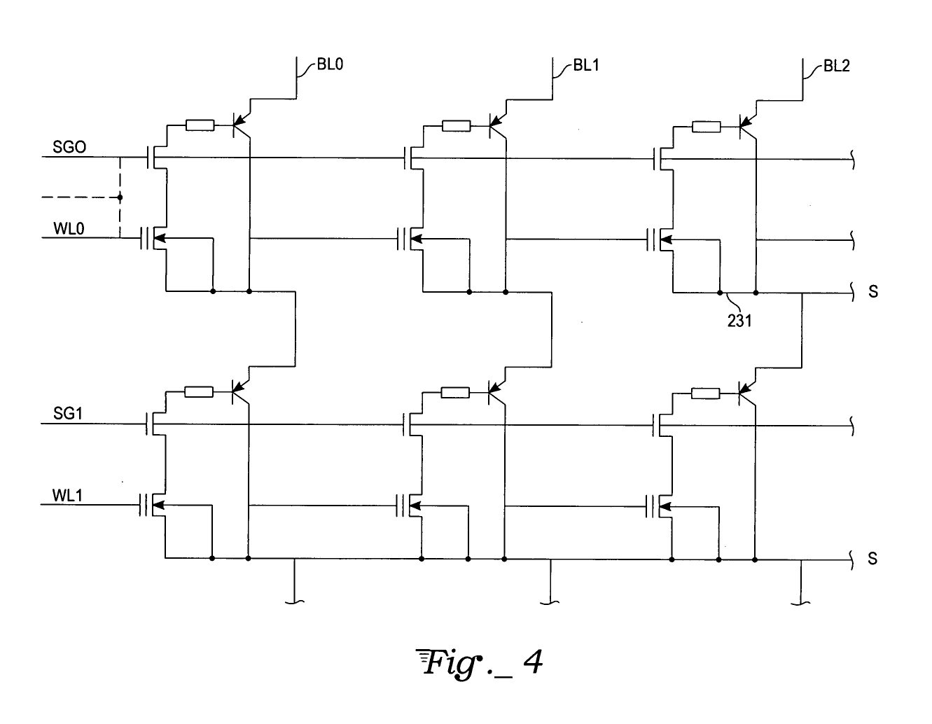

Although a NOR memory array is shown, the memory cells could be arranged in a NAND configuration, as in FIG. 4. All voltages for program and erase are the same. Although EEPROM memory cells are shown, flash cells of the type shown in FIG. 1 could be substituted. In fact, any lateral MOS non-volatile memory cell can be combined with a vertical bipolar transistor as long as layers of the memory device allow construction or selection of p-n and n-p junctions to form a virtual or parasitic bipolar transistor.

1. A non-volatile memory cell comprising:
a non-volatile memory device having a source and drain in an active region of a semiconductor substrate having regions of p and n conductivity types with a plurality of p-n junctions and a floating gate electrically insulated from the source and drain but in electrical charge carrier communication with at least one of the source, drain and substrate; and
a bipolar transistor formed by p-n junctions in said active region of the non-volatile memory device and having at least one electrode electrically communicating with one of the source and drain of the non-volatile memory device in a manner delivering output current from the non-volatile memory device.

2. The memory cell of claim 1 wherein the memory device is a lateral device and said bipolar transistor is a vertical transistor.

3. The memory cell of claim 1 wherein the non-volatile memory device is an EEPROM transistor and a connected select transistor.

4. The memory cell of claim 1 wherein the non-volatile memory device is a flash transistor.

5. The memory cell of claim 3 replicated in a NAND memory array.

6. The memory cell of claim 3 replicated in a NOR memory array.

7. The memory cell of claim 4 replicated in a NAND memory array.

8. The memory cell of claim 4 replicated in a NOR memory array.

9. The memory cell of claim 1 wherein the bipolar transistor has an emitter, a base and a collector, the emitter connected to a shallow implant region within one of the source and the drain of the non-volatile memory device.

10. The memory cell of claim 1 wherein the bipolar transistor has a base connected to one of the source and drain of the non-volatile memory device.

11. A non-volatile memory cell comprising:
a floating gate memory device formed using a semiconductor substrate having a surface and a subsurface epitaxial layer of a first conductivity type, a well of a second conductivity type in the subsurface epitaxial layer and lesser regions of both the first and second conductivity types in the well, two of the lesser regions forming source and drain for the floating gate memory device with at least one of the source and drain having a contact region of a different conductivity type, the first and second conductivity types forming p-n junctions, and
a reverse biased junction and a forward biased junction among said p-n junctions, the junctions having contacts forming a bipolar transistor, the contacts operating as an output driver for the floating gate memory device.

12. The memory cell of claim 11 wherein the epitaxial layer is n-type semiconductor material.

13. The memory cell of claim 11 wherein the well is p-type semiconductor material.

14. The memory cell of claim 11 wherein the lesser regions are n-type semiconductor material.

15. The memory cell of claim 11 wherein the bipolar transistor has said contact regions in a vertical layer structure.

16. The memory cell of claim 11 wherein the bipolar transistor comprises an emitter region above a base region which is in turn above a collector region.

17. The memory cell of claim 1 wherein the non-volatile memory device is an EEPROM transistor connected to a select transistor.

18. The memory cell of claim 1 wherein the non-volatile memory device is a flash transistor.

19. A method of making a non-volatile memory cell comprising:
building a non-volatile memory transistor upon a semiconductor substrate using a plurality of layers and regions within layers of different conductivity types, the memory transistor having an output line, and
building a bipolar transistor associated with the non-volatile memory transistor by selecting regions and layers of different conductivity types.

20. A method of making a non-volatile memory cell comprising:
growing an epitaxial layer of a first conductivity type on a semiconductor substrate of a second conductivity type, a portion of the epitaxial layer formed into a deep well of the second conductivity type,
forming a shallow well of the second conductivity type in the deep well,
forming spaced apart source and drain regions of the first conductivity type in the shallow well,
forming a first shallow doped region of the second conductivity type in one of the source and drain regions,
forming a second shallow doped region of the second conductivity type in the shallow well,
forming a conductive floating gate insulatively spaced over the substrate and spaced over source and drain regions,
forming a control gate insulatively spaced over the floating gate, thereby completing a floating gate memory transistor having at least one output line, and
arranging the first shallow doped region for bias relative to the source and drain regions where the first shallow doped region is formed, said bias being one of forward and reverse bias, and arranging bias on the deep well relative to the shallow well, said bias of the deep well being the other of forward and reverse bias thereby establishing a bipolar transistor amplifier beneath the memory transistor and having an output along said output line.
